(19) United States
(12) Patent Application Publication
(10) Pub. No.: US 2014/0184224 A1
(43) Pub. Date: Jul. 3, 2014

(54) MAGNETIC RESONANCE METHOD FOR ANALYZING PORE SIZE DISTRIBUTION

(71) Applicants: Uri Nevo, Kadima (IL); Dan Benjamini, Tel-Aviv (IL)

(72) Inventors: Uri Nevo, Kadima (IL); Dan Benjamini, Tel-Aviv (IL)

(73) Assignee: RAMOT AT TEL-AVIV UNIVERSITY LTD., Tel-Aviv (IL)

(21) Appl. No.: 14/237,911

(22) PCT Filed: Aug. 9, 2012
(86) PCT No.: PCT/IL2012/050307

§ 371 Date: Feb. 10, 2014

Related U.S. Application Data
(60) Provisional application No. 61/521,847, filed on Aug. 10, 2011.

(51) Int. Cl. G06T 7/00; G01R 33/54

(52) U.S. Cl. CPC G06T 7/0012; G01R 33/54
USPC 324/318; 382/131

(57) ABSTRACT

A method of magnetic resonance analysis of a porous structure is disclosed. The method comprises: obtaining a recorded magnetic resonance signal as a function of both a magnetic resonance wavevector and a magnetic resonance angle, in response to a series of magnetic resonance experiments, each featuring a plurality of pairs of bipolar gradient pulse subsequences being characterized by a respective magnetic resonance wavevector and a respective magnetic resonance angle, where the respective magnetic resonance angle is an angle between gradient directions of the bipolar gradient pulse subsequences. The method further comprises performing an at least three-dimensional analysis of the magnetic resonance signal, so as to extract a pore size distribution from the structure; and issuing a report regarding the analysis.

### RELATED APPLICATION

This application claims the benefit of priority of U.S. Provisional Patent Application No. 61/521,847 filed Aug. 10, 2011, the contents of which are incorporated herein by reference in their entirety.

### FIELD AND BACKGROUND OF THE INVENTION

The present invention, in some embodiments thereof, relates to magnetic resonance analysis and, more particularly, but not exclusively, to magnetic resonance analysis of a porous structure.

Magnetic resonance (MR) analysis is a method to obtain the chemical and physical microscopic properties of materials, by utilizing a quantum mechanical phenomenon, named Nuclear Magnetic Resonance (NMR), in which a system of spins, placed in a magnetic field resonantly absorb energy, when applied with a certain frequency.

A nucleus can experience NMR only if its nuclear spin I does not vanish, i.e., the nucleus has at least one unpaired nucleon. Examples of non-zero spin nuclei frequently used in magnetic resonance include ¹H (I=1/2), ²H (I=1), ²³Na (I=3/2), etc. When placed in a magnetic field, a nucleus having a spin I is allowed to be in a discrete set of energy levels, the number of which is determined by I, and the separation of which is determined by the gyromagnetic ratio of the nucleus and by the magnetic field. Under the influence of a small perturbation, manifested as a radiofrequency magnetic field, which rotates about the direction of a primary static magnetic field, the nucleus has a time dependent probability to experience a transition from one energy level to another. With a specific frequency of the rotating magnetic field, the transition probability may reach the value of unity. Hence at certain times, a transition is forced on the nucleus, even though the rotating magnetic field may be of small magnitude relative to the primary magnetic field. For an ensemble of spin I nuclei the transitions are realized through a change in the overall magnetization.

Once a change in the magnetization occurs, a system of spins tends to restore its magnetization longitudinal equilibrium value, by the thermodynamic principle of minimal energy. The time constant which control the elapsed time for the system to return to the equilibrium value is called “spin-lattice relaxation time” or “longitudinal relaxation time” and is denoted T1. An additional time constant, T2 (≦T1), called “spin-spin relaxation time” or “transverse relaxation time”, controls the elapsed time in which the transverse magnetization diminishes, by the principle of maximal entropy. However, inter-molecule interactions and local variations in the value of the static magnetic field, alter the value of T₂, to an actual value denoted T₂*.

In MR analysis, pulse sequences are applied to the object to generate NMR signals and obtain information therefrom which is subsequently used to analyze the object. The above mentioned relaxation times and the density distribution of the nuclear spin are properties which vary from one object to the other, and therefore allows the analysis of the object. In diffusion-weighted MR analysis, for example, magnetic field gradients are applied so as to provide motion-related contrast which is sensitive to motion of fluid molecules in selected directions. Diffusion-weighted MR analysis exploits the random motion of the molecules which causes a phase dispersion of the spins with a resultant signal loss. Such analysis can be used for characterizing morphological features of pores that are embedded within porous media, wherein molecules are diffusing within the pores in restricted manner.

Diffusion NMR is an efficient tool in probing noninvasively the microstructure of water-filled porous materials. A pair of gradients encodes displacement of molecules into phase shift of their respective NMR signal. Random Brownian displacement thus dephases the NMR signal of ensembles of spins, causing measureable signal attenuation [Callaghan et al., “Diffraction-like effects in NMR diffusion studies of fluids in porous solids,” Nature, 351:467-469, 1991; Callaghan, “NMR Imaging, NMR Diffraction and Applications of Pulsed Gradient Spin Echoes In Porous Media,” Science, 14:701-709, 1996].

A known technique for observing diffusion in porous media employs the so-called pulsed field gradient (PFG) sequence, wherein a pair of magnetic field gradient pulses is applied to encode displacements between the application of these two pulses.

U.S. Pat. No. 7,053,611, for example, discloses a method that includes acquiring a suite of NMR measurements of a fluid sample using a single-polar PFG (s-PFG) sequence for encoding diffusion information, wherein each NMR measurement in the suite is acquired with a different value in a parameter in the pulsed field gradient pulses for producing a different diffusion effect. The suite of NMR measurements is inverted to produce a distribution function that relates diffusion properties of the fluid sample with the longitudinal and/or transverse magnetic relaxation time thereof.

Bipolar PFG sequences have been used in medical imaging applications for measuring diffusion in heterogeneous laboratory samples in which the applied magnetic field is very homogeneous, but produces internal gradients because of the nature of the material of the sample. Additionally, bipolar PFG sequences have been used for measuring diffusion and relaxation of reservoir fluids in the pore spaces of earth formations surrounding a borehole (U.S. Pat. No. 5,796,252).

U.S. Published Application No. 20100033182 teaches a multi-PFG experiment, which involves the application of repeated pairs of diffusion gradients, and in particular a double PFG (d-PFG) sequence which includes two pairs of diffusion gradient pulses. An estimate of the size characteristic of a distribution of restricted compartments of the sample is generated based on the received MR signal.

Additional background art includes [Basser et al., “MR diffusion tensor spectroscopy and imaging. Biophysical journal, 66(1):259-67, 1994; Komlosh et al., “Detection of microscopic anisotropy in gray matter and in a novel tissue phantom using double Pulsed Gradient Spin Echo MR,” Journal of magnetic resonance (San Diego, Calif.: 1997), 189(1):38-45, November 2007; Shemesh et al., “Noninvasive bipolar double-pulsed-field-gradient NMR reveals signatures for pore size and shape in polydisperse, randomly oriented, inhomogeneous porous media,” Journal of chemical physics, 133(4):044705, July 2010; Shemesh et al., “From single-pulsed field gradient to double-pulsed field gradient MR: gleaning new microstructural information and developing new forms of contrast in MRI,” NMR in biomedicine, (November 2009):757-780, August 2010; Karlicek et al., “A modified pulsed gradient technique for measuring diffusion in the presence of large background gradients,” Journal of Magnetic Resonance (1969), 37(1):75-91, January 1980; and Ozarslan et al., “A general framework to quantify the effect of restricted diffusion on the NMR signal with applications to double pulsed field gradient NMR experiments,” Journal of chemical physics, 130(10):104702, March 2009.

### SUMMARY OF THE INVENTION

According to an aspect of some embodiments of the present invention there is provided a method of magnetic resonance analysis of a porous structure. The method comprises: obtaining a recorded magnetic resonance signal as a function of both a magnetic resonance wavevector q and a magnetic resonance angle φ, in response to a series of magnetic resonance experiments, each featuring a plurality of pairs of bipolar gradient pulse subsequences being characterized by a respective magnetic resonance wavevector q and a respective magnetic resonance angle φ, where φ is an angle between gradient directions of the bipolar gradient pulse subsequences; performing an at least three-dimensional analysis of the magnetic resonance signal, so as to extract a pore size distribution from the structure. Optionally and preferably the method comprises issuing a report regarding the analysis.

According to some embodiments of the invention the three-dimensional analysis comprises solving a linearized three-dimensional set of equations.

According to some embodiments of the invention the method further comprising selecting a plurality of predetermined and different pore sizes, and calculating an expected signal for each value of the magnetic resonance wavevector q and the magnetic resonance angle φ.

According to some embodiments of the invention the analysis comprises calculating a vector of coefficient for the matrix.

According to some embodiments of the invention the method comprises, for each experiment, generating a respective plurality of pairs of bipolar gradient pulse subsequences and acquiring a respective magnetic resonance signal generated in response to the pairs of bipolar gradient pulse subsequences.

According to some embodiments of the invention the structure comprises at least one object selected from the group consisting of a sediment, a rock, a heterogeneous catalyst, a porous polymer, an emulsion product, a biological cell, a tissue, a central-nervous-system tissue, quartz sand and a yeast cell.

According to some embodiments of the invention the structure comprises at least one structure selected from the group consisting of soil and rock and the method further comprising using the pore size distribution for assessing hydrocarbon content or production potential of the structure.

According to some embodiments of the invention the structure is wet.

According to some embodiments of the invention the structure is immersed in a liquid.

According to an aspect of some embodiments of the present invention there is provided a computer software product. The computer software product comprises a computer-readable medium in which program instructions are stored, which instructions, when read by a computer, cause the computer to receive a recorded magnetic resonance signal, to analyze the signal according to the method described above. Optionally and preferably the instructions cause the computer to communicate a report regarding the analysis.

According to an aspect of some embodiments of the present invention there is provided a system for magnetic resonance analysis. The system comprises; a radiofrequency system configured for generating a plurality of pairs of bipolar gradient pulse subsequences, and acquiring a magnetic resonance signal as a function of both a magnetic resonance wavevector q and a magnetic resonance angle φ, in response to a series of magnetic resonance experiments, each featuring a plurality of pairs of bipolar gradient pulse subsequences being characterized by a respective magnetic resonance wavevector q and a respective magnetic resonance angle φ, where φ is an angle between gradient directions of the bipolar gradient pulse subsequences. The system also comprises a processing system configured for performing an at least three-dimensional analysis of the magnetic resonance signal, so as to extract a pore size distribution from the structure. Optionally and preferably the processing system is configured for communicating a report regarding the analysis.

According to some embodiments of the invention the processing system is configured for solving a linearized three-dimensional set of equations.

According to some embodiments of the invention the linearized three-dimensional set of equations is formula table into a matrix whose columns represent pore sizes wherein the entries in each column vary as a function of the magnetic resonance wavevector q and the magnetic resonance angle φ.

According to some embodiments of the invention the processing system is configured for calculating, for each of a plurality of predetermined and different pore sizes, an expected signal for each value of the magnetic resonance wavevector q and the magnetic resonance angle φ.

According to some embodiments of the invention the analysis comprises calculating a vector of coefficient for the matrix.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks manually, automatically, or a combination thereof. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of method and/or system as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE DRAWINGS

Some embodiments of the invention are herein described, by way of example only, with reference to the accompanying drawings. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of an s-PFG sequence;

FIGS. 2A-B are schematic illustrations of a single-pair bipolar PFG sequence (FIG. 2A) and the corresponding effective waveform (FIG. 2B);

FIGS. 3A-B are schematic illustrations of d-PFG sequences, according to some embodiments of the present invention;

FIGS. 4A-D are schematic illustrations of pulse sequences which comprise two pairs of bipolar gradient pulse subsequences (FIGS. 4A and 4C) and the corresponding effective waveforms (FIGS. 4B and 4C), according to some embodiments of the present invention;

FIG. 5 is a schematic illustration of a space which can be spanned by the technique of the present embodiments;

FIG. 6 is a flowchart diagram describing a method suitable for magnetic resonance analysis of a sample according to some embodiments of the present invention.

FIG. 7 is a schematic illustration of a system for magnetic resonance analysis of a sample, according to some embodiments of the present invention.

FIG. 8 shows angular wavevector space signal attenuation curves, as obtained in experiments performed according to some embodiments of the present invention;

FIGS. 9A-C shows pore size distribution histograms for capillary phantoms, as obtained in experiments performed according to some embodiments of the present invention;

FIGS. 10A-B shows SEM images of 5000 (FIG. 10A) and 10,000 (FIG. 10B) RPM homogenization rates, as obtained in experiments performed according to some embodiments of the present invention;

FIGS. 11A-C shows pore size distribution histograms for bioresorbable films, as obtained in experiments performed according to some embodiments of the present invention;

FIGS. 12A-D show pore size distribution histograms for four different polymers, as obtained in experiments performed according to some embodiments of the present invention;

FIG. 13 shows angular wavevector signal attenuation curves, as obtained in experiments performed according to some embodiments of the present invention; and

FIG. 14 shows an example of a three-dimensional set of equations which is formulated according to some embodiments of the present invention into a matrix.

### DESCRIPTION OF SPECIFIC EMBODIMENTS OF THE INVENTION

The present invention, in some embodiments thereof, relates to magnetic resonance analysis and, more particularly, but not exclusively, to magnetic resonance analysis of a porous structure.

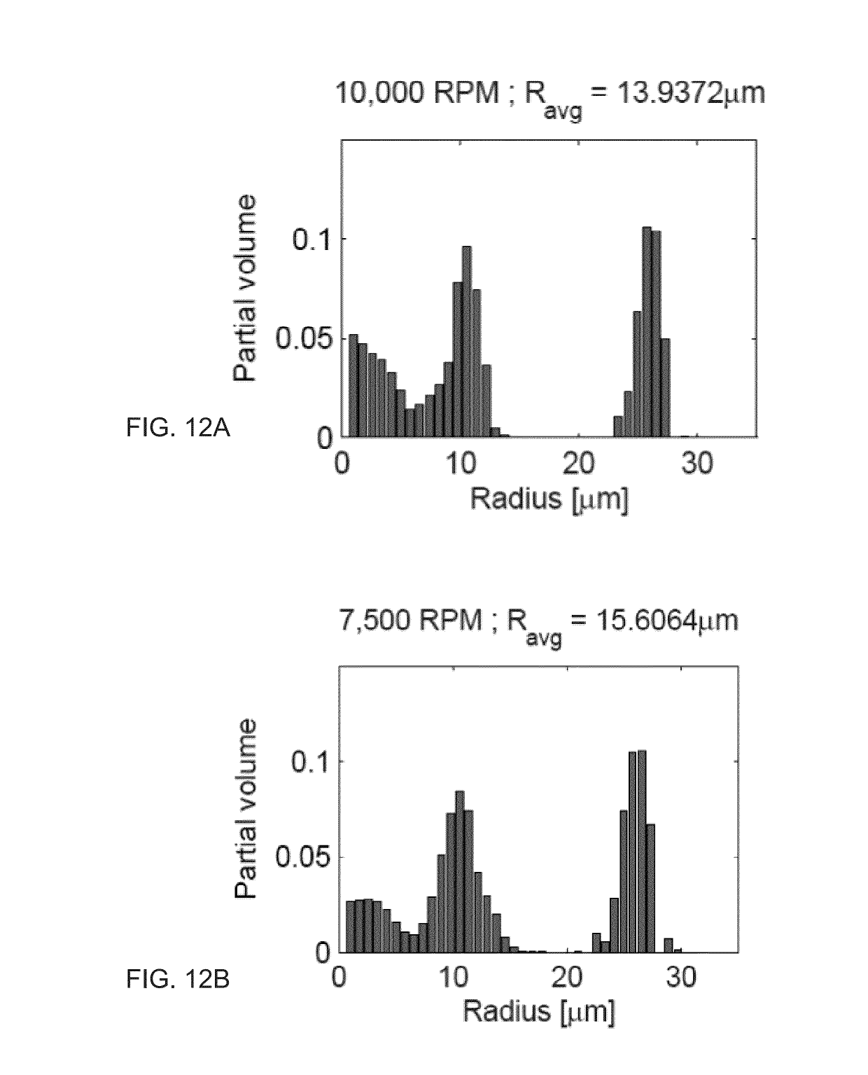

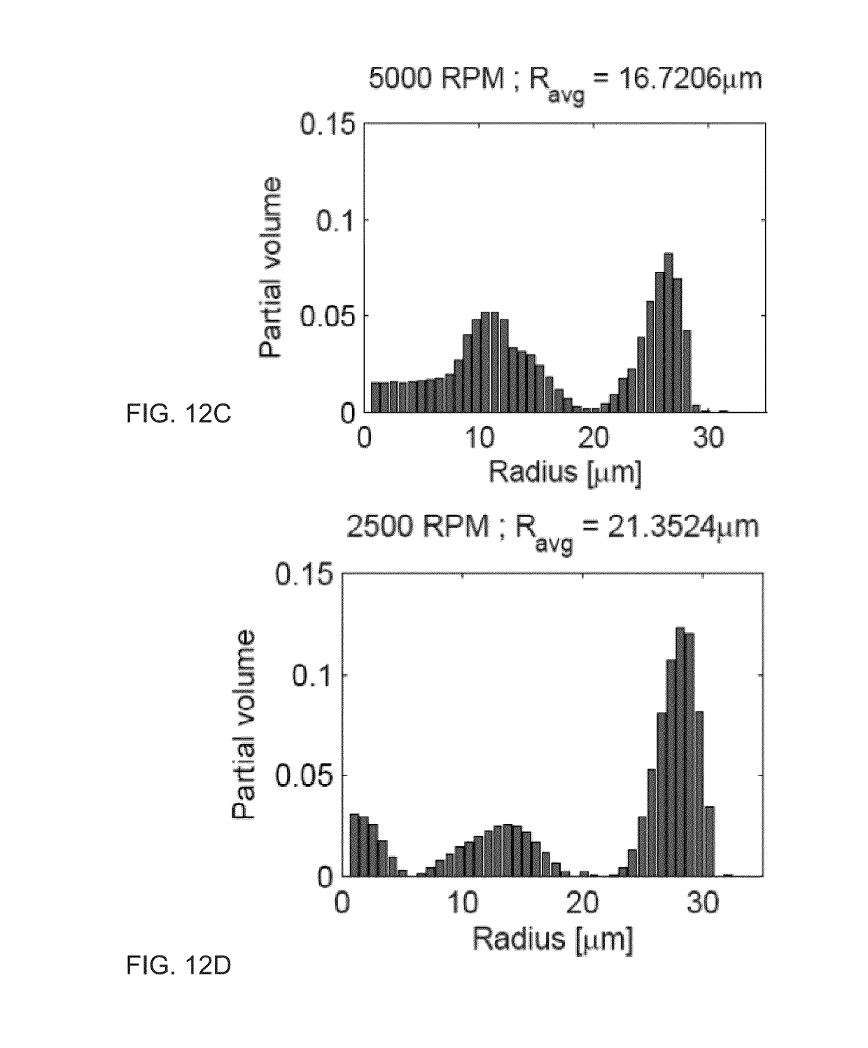

For purposes of better understanding some embodiments of the present invention, as illustrated in FIGS. 2-14, reference is first made to several types of gradient pulse sequences.

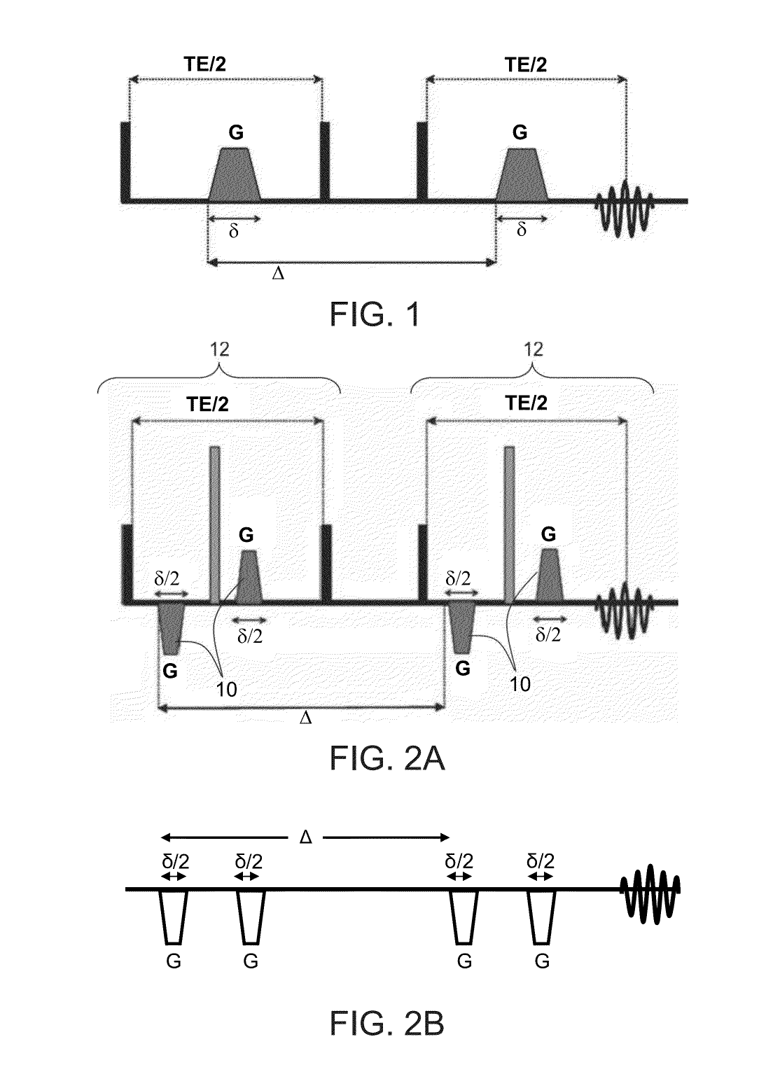

FIG. 1 illustrates an s-PFG sequence (also referred in the literature as a uni-polar PFG sequence). This sequence is composed of one pair of subsequences each having one gradient pulse and one or more radiofrequency pulses. Each gradient pulse is denoted G. The width of each gradient pulse is denoted δ and the time interval between the two gradient pulses is denoted Δ.

The radiofrequency pulses are shown as vertical black bars. In the representative example shown in FIG. 1, the gradient pulses are embedded in the so-called stimulated echo radiofrequency sequence which includes three 90° pulses. Specifically, each gradient pulse is preceded with a 90° radiofrequency pulse, with an additional 90° pulse after the first gradient pulse so that there are two 90° pulses between the gradient pulses. Thus, the first subsequence includes a gradient pulse between two 90° radiofrequency pulses, and can therefore be written symbolically as “90-G-90.” The time difference between the first and second 90° pulses of this subsequence is TE/2, where TE denotes the echo time. The second subsequence includes a gradient pulse preceded by a 90° radiofrequency pulse and can therefore be written symbolically as “90-G.” The time difference between the 90° pulse of this subsequence and the acquisition time is also TE/2.

The pair of diffusion gradient pulses of the s-PFG sequence sensitizes the MR signal to molecular displacement during the time interval Δ between the two gradients, and the resulting signal decay is a manifestation of the diffusion processes that occur within the excited volume.

Some s-PFG methodologies employ Diffusion Tensor Imaging (DTI) which is conducted at low magnitudes of the MR wavevector q, defined as q=γδG/2π, where γ, δ and G are the gyromagnetic ratio, the gradient duration and the gradient vector, respectively.

Throughout this application, vector quantities are denoted using underlined or bold symbols.

The magnitude of the MR wavevector q is referred to as the wavenumber and denoted q. Thus, q=|q|.

In DTI, the diffusion tensor is extracted, and the tensor components yield measures for pore anisotropy. DTI is useful for characterizing coherently placed anisotropic structures in normal and diseased CNS tissues [Basser et al., NMR Biomed. 15, 456 (2002); Mori et al., Ann. Neurol. 45, 265 (1999); and Horsfield et al., NMR Biomed. 15, 570 (2002)].

For higher values of the MR wavenumber, a q-space MR technique is employed. This approach utilizes the diffusion-diffraction patterns that are observed when higher q-values are reached to obtain compartmental dimensions. In q-space MR technique, the pore size can be directly derived from the minimum points of the signal decay, provided that the geometry is known. The diffusion-diffraction patterns are informative since they bear a signature for restricted diffusion. Diffusion-diffraction patterns were experimentally observed in relatively monodisperse specimens such as red blood cells (RBCs) and narrowly distributed emulsions [B. Hakansson et al., Magn. Reson. Imaging 16, 643 (1998), Kuchel et al., Magn. Reson. Med. 37, 637 (1997)].

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

Some embodiments of the present invention utilize pairs of bipolar gradient pulses.

As used herein a “pair of bipolar gradient pulses” refers to a pair of gradient pulses applied by activating the gradient coil along some axis at a first amplitude for a first period of time, and then along the same axis for a second period of time and at a second amplitude, wherein the first and second amplitudes are of opposite polarity. For clarity of presentation then term “bipolar pair” will be used as abbreviation for “pair of bipolar gradient pulses.”

FIG. 2A illustrates a pulse sequence which is composed of one pair of subsequences each having a pair of bipolar gradient pulses and one or more radiofrequency pulses.

As used herein, “a pair of bipolar subsequences,” refers to two successive bipolar subsequences in which the overall time-integral of the gradient pulses constituting the bipolar pair the first bipolar subsequence of the pair equals the overall time-integral of the gradient pulses constituting the bipolar pair the second bipolar subsequence of the pair. Formally, denoting the magnitudes of the gradients of the bipolar pair of the first subsequence by G₁ₐ and G_{1b}, and the magnitudes of the gradients of the bipolar pair of the first subsequence by G₂ₐ and G_{2b}, in a pair of bipolar subsequences, the following relation applies:

$${\int }_{t 1}^{t 2} {G}_{1 a} d t + {\int }_{t 3}^{t 4} {G}_{1 b} d t = {\int }_{t 5}^{t 6} {G}_{2 a} d t + {\int }_{t 7}^{t 8} {G}_{2 b} d t$$

where, t₁, . . . , t₈ denote the beginning and end time-points of the respective gradient pulses (e.g., G₁ₐ is applied by activating the respective gradient coil at time t₁ and deactivating the respective gradient coil at t₂; G_{1b} is applied by activating the respective gradient coil at time t₃ and deactivating the respective gradient coil at t₄, and so on).

A bipolar subsequence may optionally include one or more radiofrequency pulses as known in the art. Representative examples include, without limitation, radiofrequency pulses forming the so called “spin echo” sequence (a 90° pulse followed by a 180° pulse), and radiofrequency pulses forming the aforementioned stimulated echo sequence. In some embodiments of the present invention a bipolar subsequence includes a radiofrequency pulse (e.g., 180° pulse) between the individual gradient pulses of the bipolar pair.

The pulse sequence shown in FIG. 2A is referred to as a single-pair bipolar PFG sequence. Each bipolar pair is designated 10, and each bipolar subsequence is designated 12. In the present example, bipolar subsequence 12 includes bipolar pair 10, a 180° radiofrequency pulse between the individual gradient pulses of bipolar pair 10 and a 90° radiofrequency pulse before the first gradient pulse of bipolar pair 10. The first subsequence also includes a 90° radiofrequency pulse after the second gradient pulse of bipolar pair 10. The resulting waveform associated with the sequence of FIG. 2A is schematically illustrated in FIG. 2B.

The width of each individual gradient pulse of pair 10 is δ/2, namely half the width of a single gradient pulse of the s-PFG pair (cf. FIG. 1). In other words, the total time during which the gradient coils are operative is the same for producing pair 10 as for producing a single gradient pulse in the s-PFG pair. Thus, the difference between the s-PFG sequence and the single-pair bipolar sequence is that in the latter a complex including a bipolar pair and an intermediate 180° pulse is substituted for each gradient pulse of the former.

The single-pair bipolar PFG sequence reduces the contribution from the scalar product of the applied and static gradient vectors, and recovers diffusion-diffraction patterns in inhomogeneous magnetic field.

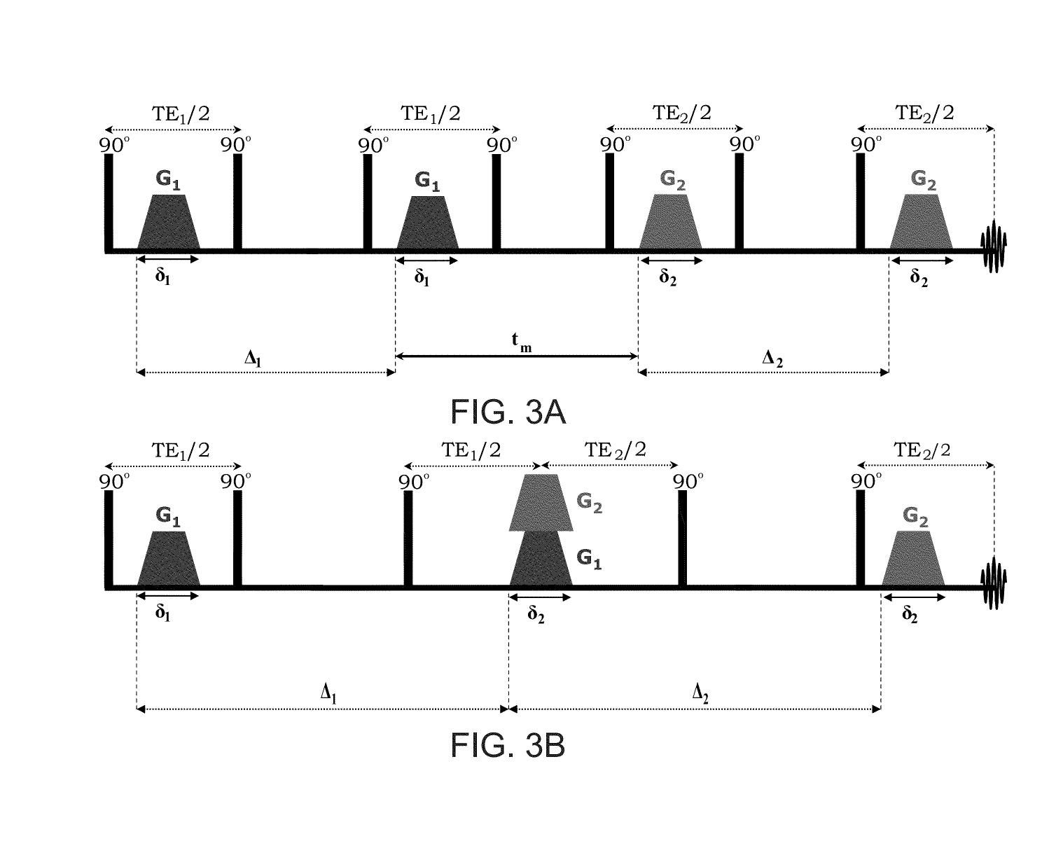

FIGS. 3A-B illustrate d-PFG sequences. Each d-PFG sequence comprises two s-PFG sequences, namely two pairs of gradient pulses and several radiofrequency pulses. The gradient pulses of the first gradient pair are denoted G₁, and the gradient pulses of the second gradient pair are denoted G₂. G₁ and G₂ are typically at an angle φ(not shown in FIGS. 3A-B) with respect to each other. The widths of G₁ and G₂ are denoted δ₁ and δ₂, respectively; the time interval between the first G₁ and the second G₁ is denoted Δ₁; the time interval between the first G₂ and the second G₂ is denoted Δ₂; and the time interval between the second G₁ and the first G₂, which is also referred to as the mixing time, is denoted tₘ. FIG. 3A illustrates a d-PFG sequence with tₘ>0 and FIG. 3B illustrates a d-PFG sequence with tₘ=0.

As in FIGS. 1 and 2A above, the radiofrequency pulses are shown in FIGS. 3A-B as vertical black bars. The sequence in FIG. 3A includes four sequential subsequences, using the above symbolic notation, these subsequences can be written as “90-G₁-90”, “90-G₁-90”, “90-G₂-90” and “90-G₂”. For the first and second subsequences, the time interval between the two 90° pulses of the respective subsequence, are denoted TE₁/2 for the first and second subsequence and TE₁/2 for the third subsequence, and the time interval between the 90° pulse of the fourth subsequence and the acquisition time is TE₂/2.

The sequence in FIG. 3B includes three sequential subsequences, “90-G₁-90”, “90-G₁G₂-90” and “90-G₂”, where “G₁G₂” is to be understood that G₁ is applied simultaneously with G₂. In first and last subsequences, the time intervals between the two 90° pulses are denotes TE₁/2 and TE₂/2, respectively. In the second subsequence, the time interval between the first 90° pulse and the simultaneous gradient pulses is TE₁/2, and the time interval between the simultaneous gradient pulses and between the second first 90° pulse is TE₂/2.

The MR signal induced by the d-PFG sequence typically becomes negative at about half the wave number necessary to observe the non-monotonicity in s-PFG. This effect is referred to as zero-crossing and is analogous to the diffusion-diffraction minima in s-PFG. The zero-crossing is advantageous since it allows reducing the gradient strength, and allows determining an average pore size more robustly even when the sample contains pores with a broad distribution of sizes or pores that are locally anisotropic and randomly distributed [Özarslan 2009 supra].

Another advantage of the zero-crossings of the MR signal induced by the d-PFG sequence is that it can be used for obtaining microstructural information. This is because the q-value of zero-crossing is indicative, at least qualitatively, of the average size of the pores, and the rate of return to the ambient noise level is indicative of the width of the distribution.

An additional advantage of d-PFG is that the angular parameter φ can be used for extracting additional information. For example, local pore shape can be derived from the dependence of the signal intensity, E, on φ at different q-values, particularly at long mixing times, since the E(φ) curves are indicative of compartment shape anisotropy.

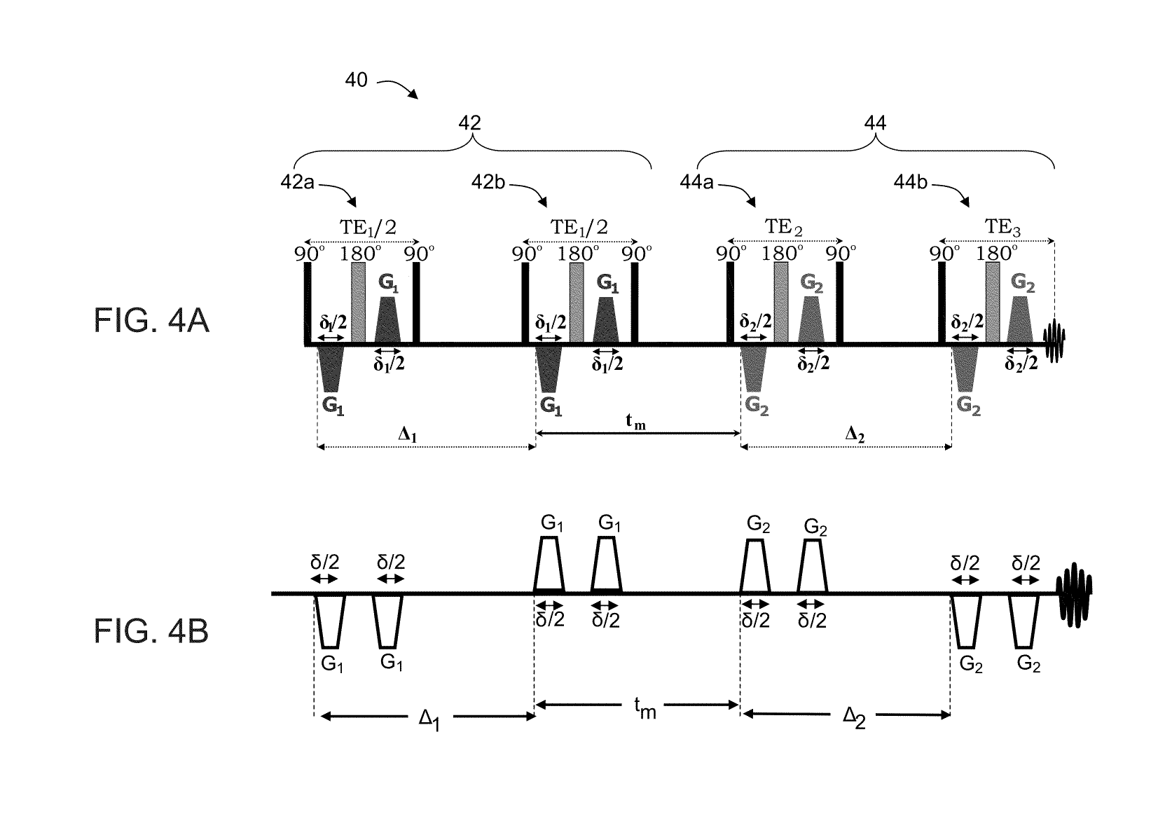

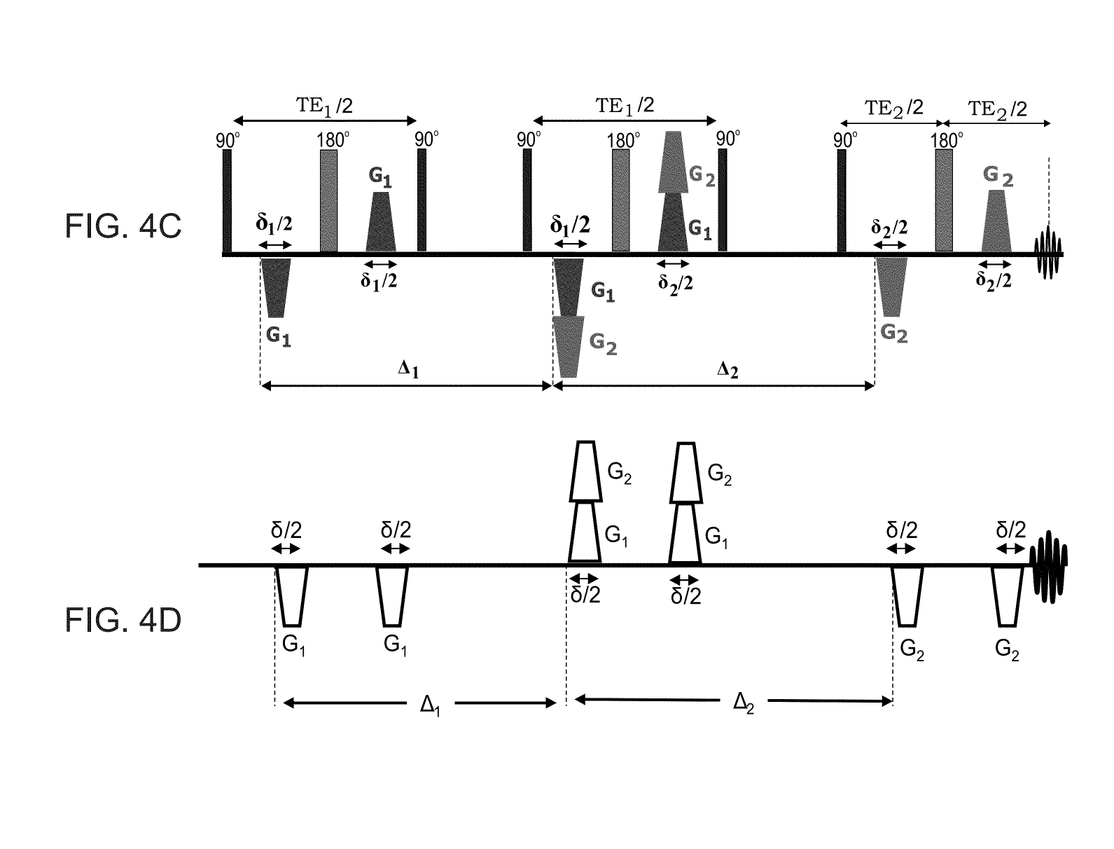

While reducing the present invention to practice it has been unexpectedly uncovered that it is advantageous to employ a pulse sequence which includes a plurality of pairs of bipolar gradient pulse subsequences. Two representative examples of such a pulse sequence are schematically illustrated in FIGS. 4A-D.

While the embodiments below are described with a particular emphasis to two pairs of bipolar subsequences, it is to be understood that more detailed reference to two pairs is not to be interpreted as limiting the scope of the invention in any way, since the pulse sequence of the present embodiments can include two or more (e.g., three or four or five) pairs of bipolar subsequences.

FIG. 4A illustrates a sequence 40, which comprises two pairs 42, 44 of bipolar subsequences. The bipolar subsequences of first pair 42 are designated 42a and 42b, and the bipolar subsequences of second pair 44 are designated 44a and 44b. The gradient pulses of pairs 42 and 44 are denoted G₁, and G₂, respectively. Since subsequences 42a, 42b, 44a and 44b are bipolar subsequences each of these subsequences comprises a bipolar pair, as further described in detail above.

In various exemplary embodiments of the invention each of subsequences 42a, 42b, 44a and 44b further comprises one or more radiofrequency pulses. The present inventors contemplate many types of radiofrequency pulses, and it is not intended to limit the scope of the present invention to any specific radiofrequency sequence. Representative example of radiofrequency pulse sequences in which the subsequences of the present embodiments can be embedded include, without limitation, spin echo sequences, stimulated echo sequences, gradient echo sequences and any combination thereof. Optionally and preferably, there is a 180° pulse between the individual gradient pulses of each bipolar pair. In some embodiments, each bipolar pair is preceded by a 90° pulse. In this embodiment, there are two 90° pulses between successive bipolar pairs.

FIG. 4B shows the resulting effective waveform corresponding to the pulse sequence shown in FIG. 4A. The first two G₁ gradients in FIG. 4B, correspond to the decomposition of the first G₁ gradient pulse of FIG. 3A into two gradients each having a duration of δ/2. These two gradients are dephasing, while the two next gradients (corresponding to the decomposition of the second G₁ gradient pulse in FIG. 3A) are both applied in a refocusing sense. The third and fourth gradients (corresponding to the decomposition of the first G₂ gradient pulse in FIG. 3A) are again dephasing, while the last two gradients (corresponding to the decomposition of the second G₂ gradient pulse in FIG. 3A) are applied in a refocusing sense to the two preceding gradients.

In the representative illustrations of FIGS. 4A-4D, all gradient pulses of pair 42 have equal widths (δ₁/2) and equal amplitudes in absolute value (G₁), and all gradient pulses of pair 44 have equal widths (δ₂/2) and equal amplitudes in absolute value (G₂), but this need not necessarily be the case since the gradient pulses need not to be of equals width or of equal amplitude, provided they satisfy the aforementioned relation regarding a pair of bipolar subsequences, Specifically, for each pair of bipolar subsequences in sequence 40, the overall time-integral of the gradient pulses constituting the bipolar pair the first subsequence of the pair equals the overall time-integral of the gradient pulses constituting the bipolar pair the second subsequence of the pair.

In some embodiments of the present invention sequence 40 comprises at least one bipolar pair in which both gradient pulses have equals widths and equal amplitudes (but opposite in polarity).

In some embodiments of the present invention sequence 40 comprises at least one pair of bipolar subsequences in which all gradient pulses have equals widths and equal amplitudes (in absolute value).

Although the gradient pulses in FIGS. 4A-D are shown as having a trapezoidal profile, this need not necessarily be the case. The presence embodiments contemplate gradient pulses of any shape, e.g., rectangular, Gaussian, and the like.

The time interval between the first and second bipolar pairs of the ith pair of subsequences (measured, e.g., between the first gradient pulses of the bipolar pairs) is denoted Δᵢ. The mixing time between pair i of subsequences and pair i+1 of subsequences is denoted t_{m,i}. For clarity of presentation, the symbol tₘ will be used below for the embodiments in which sequence 40 includes only two pairs. Shown in FIG. 4A are δ₁, δ₂, Δ₁, Δ₂ and tₘ.

For any two pairs of bipolar subsequences, the respective mixing time can be finite (i.e., non-zero) or zero, as desired. FIG. 4C schematically illustrates an embodiment in which sequence 40 includes two pairs with tₘ=0, and FIG. 4D shows the corresponding waveform.

In some embodiments of the invention the mixing time between bipolar subsequences is selected to allow determination of the shape of the pores in sample under analysis, and in some embodiments of the invention the mixing time is selected to allow detecting the presence, or estimating the level of, microscopic anisotropy or isotropy. In some embodiments of the present invention the mixing time is shorter than (e.g., less than a tenth) of the ratio d²/D, where d is the characteristic restricting length scale of the sample, and D is the diffusion coefficient. The characteristic restricting length scale is measured in units of length, e.g., microns, and the diffusion coefficient is measured in unites of area per unit time (e.g., μm²/ms). For example, the mixing time can be set to zero.

Also contemplated are embodiments in which the mixing time is long, typically on the order of the ratio d²/D or longer.

In various exemplary embodiments of the invention each of at least a few of the pairs of bipolar sequences, more preferably each pair of bipolar sequences, is characterized by a different gradient direction. For example, when there are two pairs of bipolar sequences, the (four) gradient pulses of the second pair (G₂ in FIGS. 4A-D) are at an angle φ with respect to the gradient pulses of the first pair (G₁ in FIGS. 4A-D).

The angle between the gradients of different pair of bipolar sequences is optionally and preferably utilized for extracting pore size distribution from the sample. This can be done, for example, by performing a series of magnetic resonance experiments, each featuring a plurality of pairs of bipolar gradient pulse subsequences being characterized by a respective magnetic resonance wavevector q and a respective magnetic resonance angle φ. The obtained signals from the experiments from a magnetic resonance signal S(q, φ) as a function of both a q and φ.

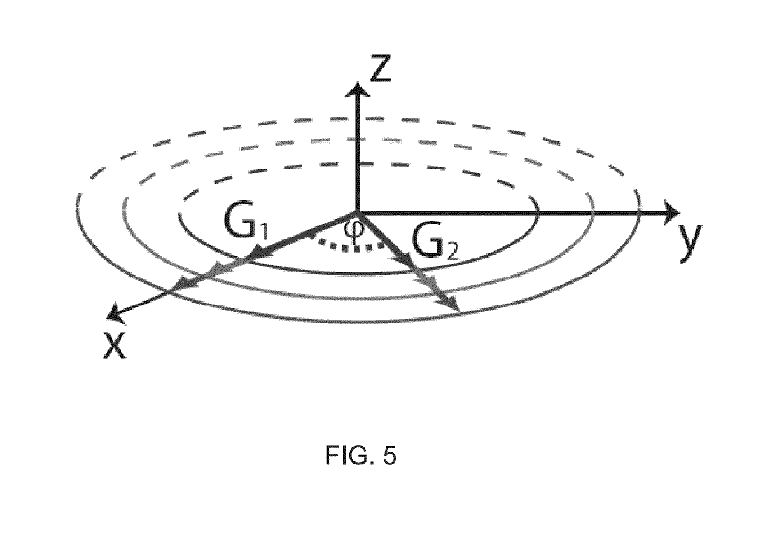

For example, the amplitude of the applied gradients and their relative direction can be varied across the series of experiments, such that the signal S is defined over a space that can be described as a plurality of virtual lines. Typically, the space is a discrete space, both in terms of the amplitudes and in terms of the angles. A representative example of such a space is illustrated in FIG. 5. In this example, the amplitudes |G₁| and |G₂| of the gradients G₁ and G₂ is the same per experiment so that the space is described as plurality of virtual concentric circles, wherein the radius of each circle equals the amplitude of G₁ and G₂ applied in the respective experiment. Experiments with |G₁|≠|G₂| are not excluded from the scope of the present invention.

Once the signal S(q, φ) is obtained, an analysis of S(q, φ) is preferably performed so as to extract a pore size distribution from the structure. In various exemplary embodiments of the invention the analysis is a three-dimensional analysis. For example, the analysis can span over a space including the wavenumber q, the MR angle φ and the pore size L of the structure. Analysis of higher dimension (e.g., four dimensions, for example, with two wavenumbers, one for each gradient in the pair) is not excluded from the scope of the present invention.

The analysis typically includes employing an optimization procedure in which a multidimensional (e.g., three-dimensional) set of equations is solved. For example, the set of equations can be is formulated into a matrix E whose columns represent the pore sizes wherein the entries in each column vary as a function of the wavevector and magnetic resonance angle. The matrix can be formulated by selecting a plurality of different pore radii, and then calculating the signal curve from them under all the experimental parameters.

A representative example of such a matrix is provided in the Examples section that follows. Optionally, the equations are linearized, and the matrix E is formulated using the linearized equations.

In various exemplary embodiments of the invention the analysis comprises calculating a vector of coefficient f for the matrix. This can be done, for example, by calculating the reciprocal matrix of E, and multiplying the reciprocal matrix by a vector representation of the signal S(q, φ).

In various exemplary embodiments of the invention a report regarding the analysis is issued. The report can be displayed on a display device, printed, or recorded on a computer readable medium from which it can be retrieved for further use. The report can include, for example, the average pore size and/or the partial volume at each of a plurality of regions of the structure. The report can alternatively or additionally include a pore size distribution histogram in a numerical and/or graphical representation. The histogram can present, for example, the partial volume for each of a plurality of radii, where each radius corresponds to a different pore size. Representative examples of such histograms are provided in the Examples section that follows.

Before providing a further detailed description of some exemplified embodiments of the present invention, attention will be given to the advantages and potential applications offered by the inventive pulse sequence.

The present embodiments are useful for noninvasive characterization of porous materials and can therefore be employed in many fields, including, without limitation, material sciences, food sciences, pharmaceutical particle characterization, oil drilling (well logging), characterization of rocks and soils in geology, tissue characterization, emulsions and porous polymers.

The present embodiments are particularly useful for the analysis of materials in which there is an unknown and optionally continuous distribution of pore sizes. The present embodiments are useful also when the diameters of the pores span over multiple scales, e.g., one or more orders of magnitude.

The present embodiments are useful for characterizing a wet porous material that is immersed in liquid, such as, but not limited to, water. For example, the present embodiments are useful for characterization of tissue samples, which can be modeled as porous materials with intracellular and extracellular water and with possible exchange in between them. The present embodiments can also be utilized for the analysis of materials, particularly with respect to their pore size distribution, so as to assess the biocompatibility and/or longevity of the analyzed materials.

The present embodiments can also be utilized in the drug discovery field, wherein the pore size distribution can be used for assessing the ability of the analyzed materials to feature controlled release of drugs and other bioactive agents. Thus, for example, the present embodiments can be utilized for analyzing a biomaterial scaffolds and/or wound dressing material.

The present embodiments can also be utilized in NMR logging, for example, for the purpose of evaluating the hydrocarbon (oil, gas, petroleum, etc) content or production potential of a subsurface formation, for example, by measuring petrophysical properties, such as the lithology or the rock type (e.g., amount of sand, shale, limestone, or more detailed mineralogical description), the porosity or fraction of the rock that is void or pore space, and the fluid saturations or fractions of the pore space occupied by oil, water and gas, petroleum and others.

It is recognized that hydrocarbon reservoirs occur beneath the earth's surface and have a structure or rock formation which is analogous to a solidified sponge. The reservoir (a rock) is made up of mineral grains, which is typically above 70%, together with a void content, which is typically below 30%. The mineral or rock content is made up of a distribution of interconnected particles (mineral grains). The void content is formed by a plurality of microscopic pores defined between the grains and it is this that comprises the storage space for the hydrocarbon (oil and/or natural gas). Differing reservoirs has different sized grains, and different sized pores and inter-connectivity.

The pose size distribution assessment according to some embodiments of the present invention can be used for determining the volume of the void content, that is to say the amount of pores (the porosity), and the degree of inter-connectivity of the pores (the permeability). This information can then be used for assessing the hydrocarbon content or production potential of the analyzed sample. Techniques for assessing void content and hydrocarbon content or production potential suitable for the present embodiments are disclosed, for example, in U.S. Published Application Nos. 20050206890 and 20110095757, the contents of which are hereby incorporated by reference.

Additional examples of samples and objects which can be analyzed using the techniques of the present embodiments include, without limitation, porous materials, biological cells, tissues, central-nervous-system (CNS) microstructures, particularly grey matter in the CNS, porous polymers, liquid crystals, heterogeneous catalysts, emulsion systems, chemical reactor beds, porous rocks and other sediments.

More specific examples include, without limitation, biological and nonbiological composite materials such as tendon, cartilage, ligament, plaques, fibrotic tissue, calcified tissue, skin, hair, nail, hoof, cuticle, leather, parchment and other hard or soft or fluid animal tissues and their derivatives, wood and other plant tissues and their derivatives, fibers, foods, agricultural materials, soil, coal, petroleum, tar, oil shale, minerals, rock, fossils, animal and plant remains and other geophysical or petrochemical materials, liquids, gases, chemicals, polymers, rubbers, ceramics, composite materials, sols, gels, colloids, porous materials and liquid crystalline materials, either singly or in combination.

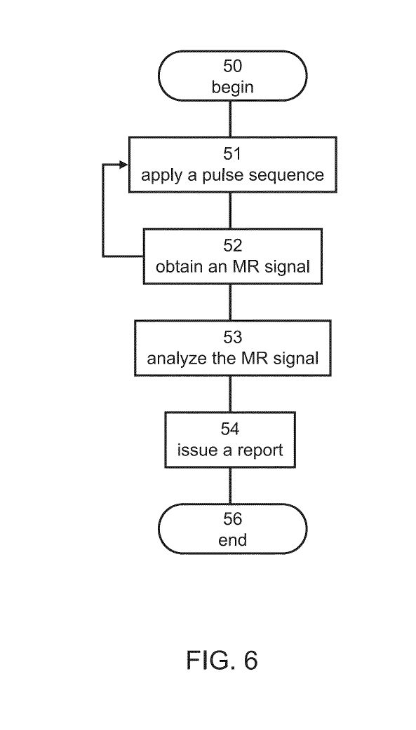

Reference is now made to FIG. 6 which is a flowchart diagram describing a method suitable for magnetic resonance analysis of a sample, according to some embodiments of the present invention.

One or more of the operations described below can be performed by a data processor. The operations can be embodied on a tangible medium such as a computer for performing the method steps. They can be embodied on a computer readable medium, comprising computer readable instructions for carrying out the operations. They can also be embodied in electronic device having digital computer capabilities arranged to run the computer program on the tangible medium or execute the instruction on a computer readable medium.

Computer programs implementing the method of this invention can commonly be distributed to users on a distribution medium such as, but not limited to, a floppy disk, CD-ROM, portable hard drive or a flash drive. From the distribution medium, the computer programs can be copied to a hard disk or a similar intermediate storage medium. The computer programs can be run by loading the computer instructions either from their distribution medium or their intermediate storage medium into the execution memory of the computer, configuring the computer to act in accordance with the method of this invention. All these operations are well-known to those skilled in the art of computer systems.

One or more of the operations described below can be performed using a magnetic resonance system. A representative example of a system suitable for the present embodiments is described below.

The method begins at 50 and optionally and preferably continues to 51 at which a pulse sequence is applied to a sample. The pulse sequence preferably comprises a plurality of pairs of bipolar gradient pulse subsequences characterized by a magnetic resonance wavevector q and a magnetic resonance angle φ as further detailed hereinabove. For example, in some embodiments sequence 40 is used.

The sample can be of any type, e.g., the aforementioned types of sample. Preferably, the sample is a porous sample.

In some embodiments of the present invention the sequence is applied with gradients magnitudes of from about 0.1 gauss/cm to about 200 gauss/cm or from about 0.25 gauss/cm to about 80 gauss/cm.

The method proceeds to 52 at which an MR signal is obtained. The MR signal can be received directly from the MR system that applies the pulse sequence or it can be a previously recorded signal, in which case the method receives the signal from the medium on which the signal is recorded. For example, the method can receive the MR signal from a computer readable medium on which the MR signal has been recorded previously.

The method optionally and preferably loops back to 51 at which the pulse sequence is applied, but with a different magnetic resonance wavevector q and/or a different magnetic resonance angle φ. The operations 51 and 52 can be repeated a plurality of times thus performing a set of experiments as further detailed hereinabove. In alternative embodiments, the method can receive the MR signal from the computer readable medium after all the experiments are performed in which case actual execution of 51 is not executed by this method.

The method continues to 53 at which the MR signal is analyzed and optionally and preferably to 54 at which a report regarding the analysis is issued, as further detailed hereinabove.

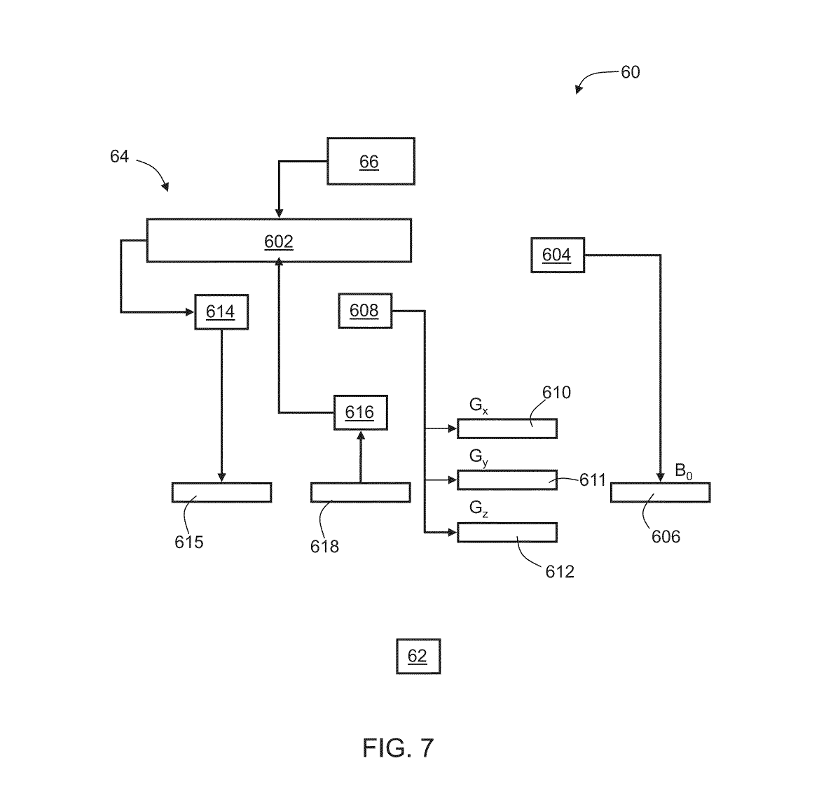

Reference is now made to FIG. 7 which is a schematic illustration of a system 60 for magnetic resonance analysis of a sample 62, according to some embodiments of the present invention.

System 60 comprises a radiofrequency system 64 configured for generating a pulse sequence, applying the pulses of the sequence to sample 62, and acquiring magnetic resonance signals from sample 62. The pulse sequence preferably comprises a plurality of pairs of bipolar subsequences, as further detailed hereinabove. System 60 optionally and preferably comprises a processing system 66, such as, but not limited to, a data processor, general purpose computer or dedicated circuitry configured for analyzing the signal, and optionally communicating a report regarding the analysis.

System 64 can be of any type known in the art. In the representative and non-limiting example illustrated in FIG. 7, system 64 comprises a main controller 602 which is configured to apply magnetic fields to sample 62. An axial magnet controller 604 is in communication with an axial magnet 606 that is generally configured to produce a substantially constant magnetic field B₀. A gradient controller 608 is configured to apply a constant or time-varying gradient magnetic field in a selected direction or in a set of directions using magnet coils 610-612 to produce respective magnetic field gradients Gₓ, G_{y}, G_{z}, or combinations thereof. A radiofrequency generator 614 is configured to deliver one or more radiofrequency pulses to sample 62 using a transmitter coil 615. A radiofrequency receiver 616 is in communication with a receiver coil 618 and is configured to detect or measure net magnetization of spins. Slice selection gradients can be applied with the same hardware used to apply the diffusion gradients.

Gradient controller 608 can be configured to produce the gradient pulses of the present embodiments along one or more axes. Gradient controller 608 can also be configured to apply gradient pulses of different magnitudes (which effect different q-values), and associated MR signals can be detected by the receiver 616.

Main controller 602 communicates with data processing system 66, and is configured for receiving control signals from system 66 and/or transmitting acquisition data (digital or analog) to system 66 for performing the analysis. System 66 can be, for example, a personal computer, a workstation, a personal digital assistant, or a networked computer. System 66 generally includes a hard disk, a removable storage medium such as a floppy disk or CD-ROM, and other memory such as random access memory (RAM). Computer-executable instructions for data acquisition or control can be provided to system 66 as described above.

Preferably, system 66 carries on at least some of the operations described above. For example, system 66 can be loaded with a computer software product which causes the system 66 to instruct radiofrequency system 64 to generate a plurality of pairs of bipolar gradient pulse subsequences. System 66 can also be loaded with a computer software product which causes system 66 to receive from system 64 an MR signal in response to a plurality of pairs of bipolar gradient pulse subsequences, to analyze signal, and optionally to communicate a report regarding analysis, e.g., to a display device. System 66 can also be configured for assessing the hydrocarbon content or production potential of the structure based on the pore size distribution, and optionally to issue a report regarding the hydrocarbon content or production potential.

It is expected that during the life of a patent maturing from this application many relevant magnetic resonance analysis systems will be developed and the scope of the term magnetic resonance analysis system is intended to include all such new technologies a priori.

As used herein the term “about” refers to ±10%.

The word “exemplary” is used herein to mean “serving as an example, instance or illustration.” Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments.” Any particular embodiment of the invention may include a plurality of “optional” features unless such features conflict.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Various embodiments and aspects of the present invention as delineated hereinabove and as claimed in the claims section below find experimental support in the following examples.

### Examples

Reference is now made to the following examples, which together with the above descriptions illustrate some embodiments of the invention in a non limiting fashion.

The development and validation of the technique of the present embodiments were obtained with two complementary experiments. Firstly, a validating setup was used to develop the method by determining the pore size histogram of a known distribution (artificially made from microcapillaries, see Methods, below). Secondly, an implementing setup that allowed derivation of the pore size distribution of porous bioresorbable polymeric films in their designated environment (aqueous surrounding, in the present example).

In the present example, a series of MR experiments, each featuring a d-PFG sequence characterized by a respective magnetic resonance wavevector q and a respective magnetic resonance angle φ, wherein in each experiment the amplitudes of the two gradients were equal, is referred to as a “Concentric d-PFG” and abbreviated CDPFG.

### Validation on Microcapillaries Phantoms

To validate the accuracy of the suggested method the CDPFG pulse sequence was applied on a phantom consisting of known pore sizes with a known size distribution. The artificial pore size distributions are presented in Table 1.

TABLE 1
Artificial pore size distribution

| Nominal Radius [μm] | D1 | D2 | D3 |
|---|---|---|---|
| 5.00 ± 1 | 0 | 0 | 0 |
| 7.50 ± 1 | 0 | 0.45 | 0.33 |
| 10.0 ± 1 | 1 | 0 | 0 |
| 12.5 ± 1 | 0 | 0 | 0.33 |
| 15.0 ± 1 | 0 | 0.55 | 0 |
| 20 ± 1.5 | 0 | 0 | 0.33 |
| 25 ± 1.5 | 0 | 0 | 0 |
| Average Radius [μm] | 5 ± 1 | 11.625 ± 1 | 13.33 ± 1.17 |

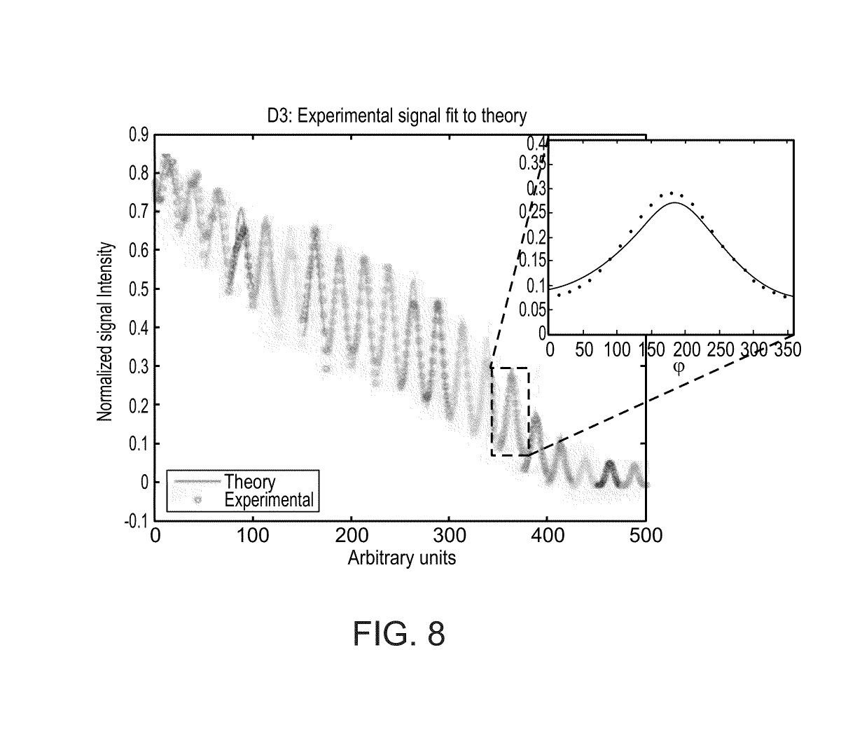

The signal obtained from the angular q-space experiment was processed using an algorithm which is described in the Methods section below. An example of such a fit (the D3 sample) is presented in FIG. 8. Notice the different colors, each representing an angular dependency curve. For each color, the amplitude of the gradient is constant and the angle φ between the gradients varies, as suggested in the magnified section in FIG. 8. As the gradient's amplitude increases, the signal is attenuated (left to right).

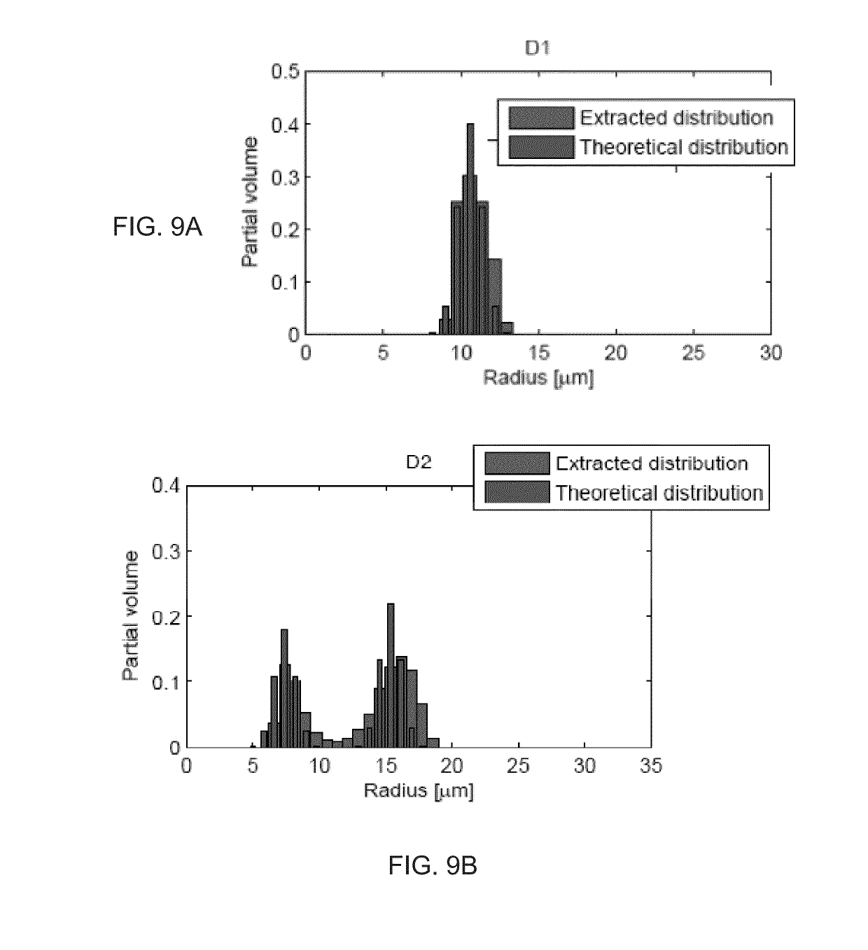

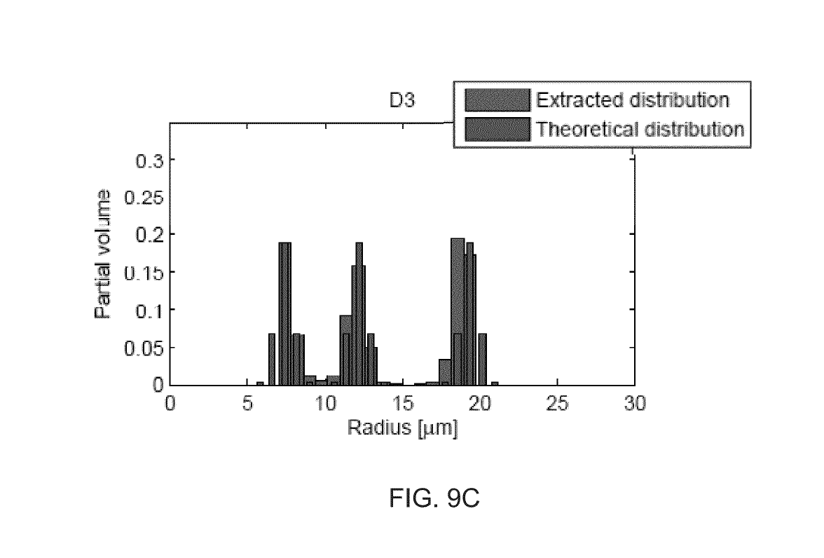

The obtained pore size distribution histograms for the capillary phantoms are shown in FIGS. 9A-C. Each artificial distribution is known and presented on top of the extracted distribution.

### Characterizing the Bioresorbable Film

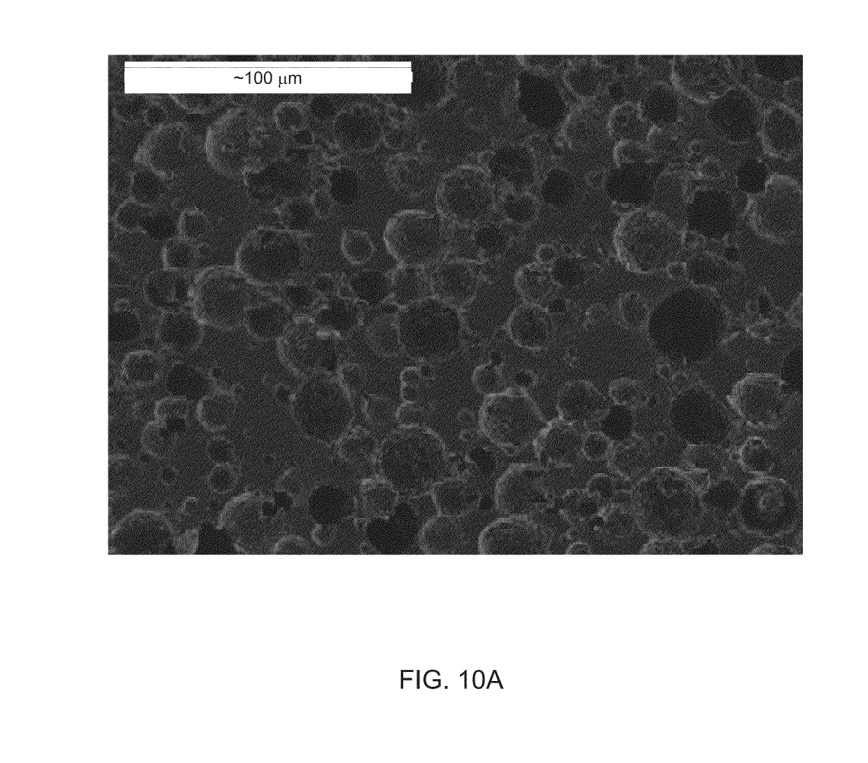

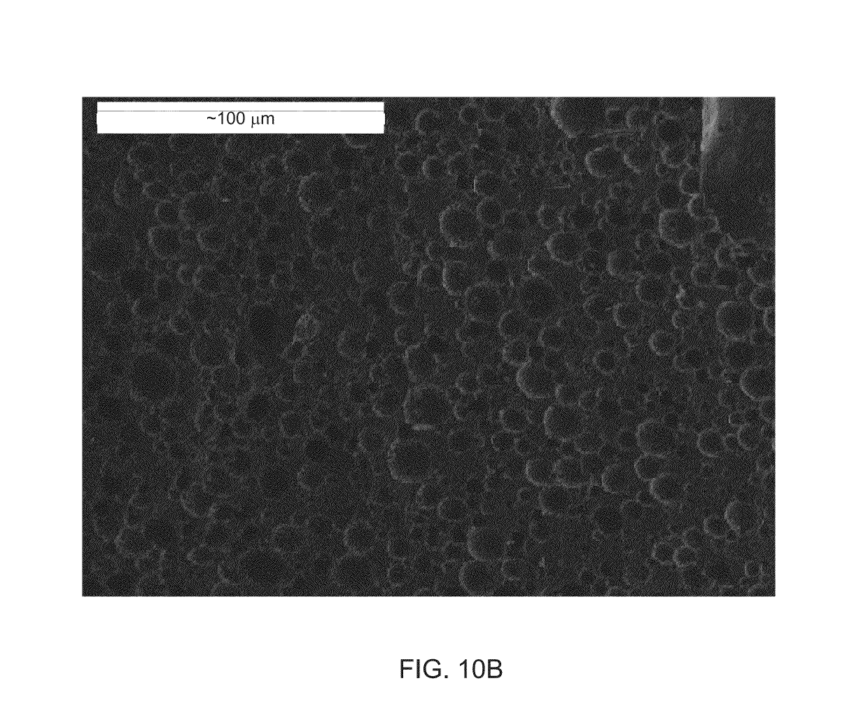

Four different bioresorbable films were analyzed. The films were synthesized with increasing homogenization rate of the emulsion (2500, 5000, 7500 and 10,000 rounds per minute (RPM), see Methods section, below). An increase in the homogenization rate results in smaller pore size, but its exact effect on the pore size distribution is yet unknown. The porous film is considered a good example of a sample with a continuous and wide pore size distribution, as shown from its SEM images in FIGS. 10A-B. Notice the very large variance in the pore's size, sometimes exceeding more than one order of magnitude.

### Pore Size Distribution on the Bioresorbable Film

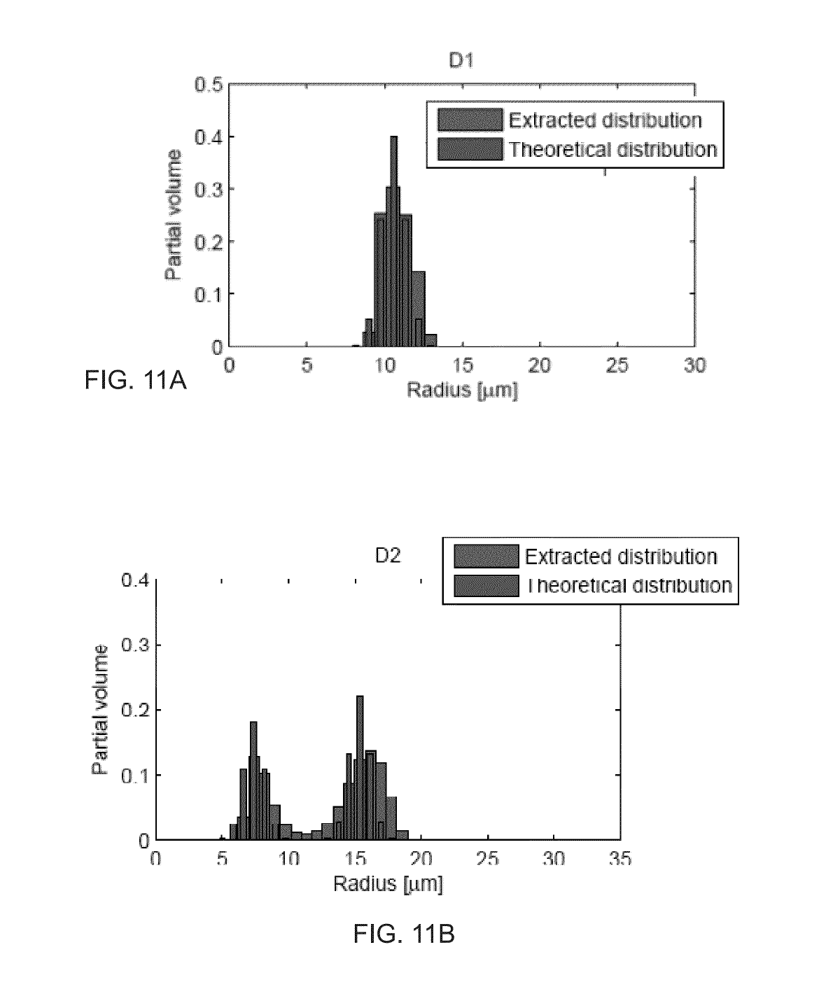

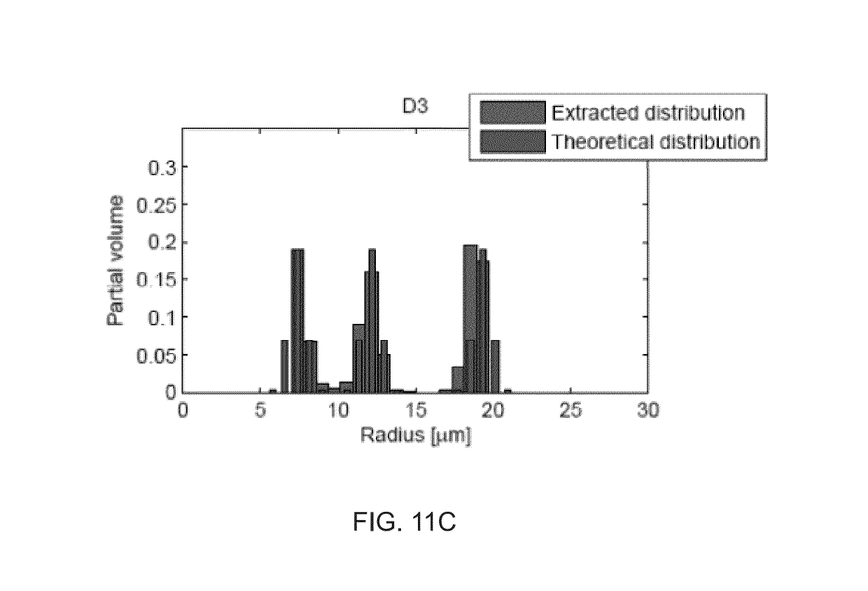

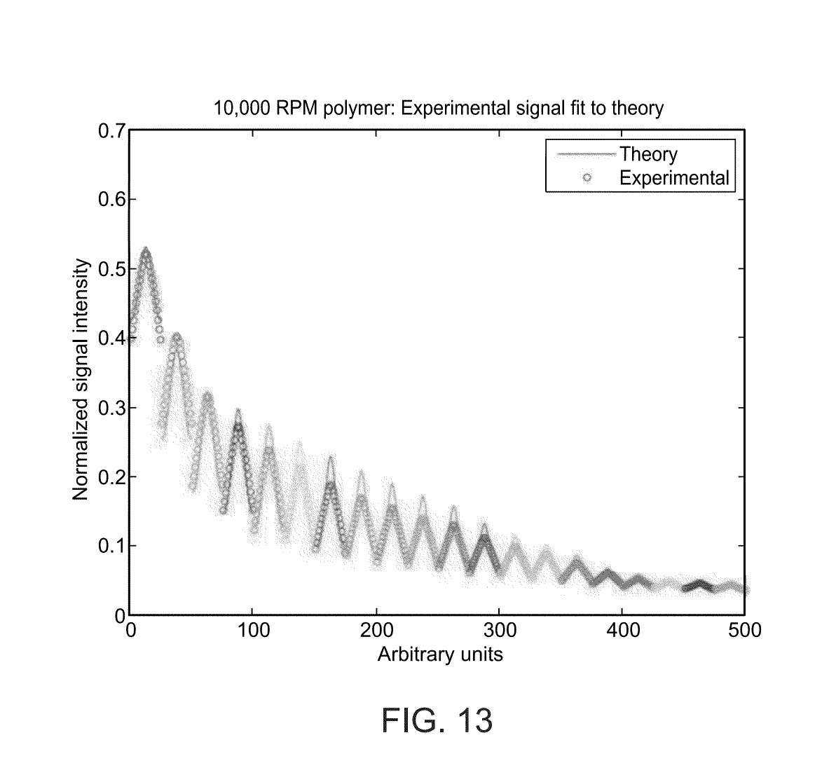

It was found by the present inventors that conventional methodology is inadequate for determining the average pore size of the porous films. On the other hand, similar to the case of the capillaries phantoms, the present inventors used the CDPFG experimental setup of the present embodiments on the polymers. Processing the data gave reproducible values for the pore size distribution and the average pores' sizes (FIGS. 11A-D). An example of such a fit (the 10 k RPM polymer) is presented in FIG. 13. Note that the average radius is in agreement with the increase of homogenization rate (i.e. smaller radius as the rate increases).

All conventional quantifications of the films were made on dry samples. These values are the first characterization of such polymers in wet conditions (aqueous surrounding, in the present example).

### Methods

### Preparation of the Micorcapillaries

Hollow microcapillaries with well defined inner diameters (PolyMicro Technologies, Phoenix, Ariz.) were cut and grouped according to Table 1. Microcapillaries were then immersed in water, exteriorly dried and packed into a 4 mm glass sleeve and inserted into a 5 mm NMR tube. The cylindrical nature of the restricting geometry was chosen since it is a simple, effective and well tested phantom for diffusion NMR experiments. The pore size distribution histogram was validated in the present example for the cylindrical geometry. However, this need not necessarily be the case, since, for some applications, it may not be necessary to employ cylindrical geometry. The method of the present embodiments is applicable also for any other geometry (such as, but not limited to, spherical geometry), e.g., by judicious selection of the boundary conditions of the governing equation, as described, for example, in Ref. [14].

### Preparation of the Bioresorbable Film

Polymeric films were prepared based on the freeze-drying of inverted emulsions technique. The aqueous phase of the inverted emulsion was based on double distilled water, while the organic phase of the inverted emulsion contained 15% (w/v) of 50/50 poly(DL-lactic-co-glycolic acid) (PDLGA), dissolved in chloroform. Freshly prepared inverted emulsions were poured into an aluminum plate and then immediately frozen in a liquid nitrogen bath. The samples were then placed in a pre-cooled (−105° C.) freeze-dryer and freeze-dried in order to preserve the microstructure of the emulsion-based structures. Before each experiment, the polymer was immersed in distilled water, and then put in a 10 mm NMR tube filled with Fluorinert (Sigma-Aldrich, Rehovot, Israel). Owing to its density and polarity differences, the Fluorinent served in keeping most extra-pores water in the upper part of the NMR tube. This part of the tube was located outside the RF coils, thus minimizing the free water content of the sample.

### NMR Experiments

A series of experiments with the sequence illustrated in FIGS. 4A-B were performed, each with a respective wavevector and angle. A stimulated echo was used in order to avoid T₂ relaxation effects due to long diffusion times. An NMR signal curve was obtained for each wavevector. It was found by the present inventors that once Δ is set, each wavevector corresponds to a different pore size population. Repeating the Angular d-PFG experiment for multiple wavevector provides the full CDPFG. The direction of a first gradient (G₁ was fixed on the x direction throughout the experiment. The direction of a second gradient (G₂) was varied in the x-y plane along the MR angle φ, as illustrated in FIG. 5. In the present example, 25 angles φ varying from 0° to 360° were employed. For each angle, 20 different gradient amplitudes were taken (where |G₁|=|G₁|), Gₘₐₓ=460 mT/m resulting in a maximal wavenumber q of 587.5 cm⁻¹, Δ=500 ms, δ=3 ms, and tm=0. Each scan with a single wavevector and angle was averaged over 16 repetitions. All scans were performed on an 8.4T NMR spectrometer (Bruker, Karlsruhe, Germany) equipped with a Micro5 probe.

### Mathematical Inverse-Problem Analysis

A porous sample represents a heterogeneous system of pore sizes. In the present example, the desired result of the inverse problem of analysis of an NMR signal was the reconstruction of a pore size histogram. In a preferred embodiment of the invention, the acquired NMR signal includes a significant component from each pore size population, to allow most or all pore sizes to be represented. In an NMR experiment, mainly two factors determine the weighting of the pore size: The diffusion gradient G (or the wavevector q) and the diffusion time Δ. Once Δ is taken large enough to allow water molecules to explore the biggest pore, the only influencing parameter left is the wavevector q. The variance in the wavevector in the CDPFG experiment of the present example allows a significant contribution of each pores' size population to the NMR signal, thus facilitating pore-size histogram reconstruction.

In the present example, it is assumed that the typical time for exchange of fluid across pores, through the pores' walls, is long relative to the diffusion time Δ. The NMR signal (in each wavevector and angular step) is a superposition of the signals resulting from different pore sizes. This implies that the inverse problem of finding the partial contribution of each pore size to the received signal curve is linear. The NMR signal Eᵣₑₛₜ (qᵢ, φᵢ, Lᵢ) of water molecules restricted in cylindrical or spherical pores of radius Lᵢ (for each value of qᵢ, φᵢ) is known. For example, it can be calculated as described in Refs. [14] and [16].

The problem can therefore be described as a linear set of equations. Formulated into a matrix equation, the known theoretical data set is defined by a three dimensional matrix E (FIGS. 11A-C) of predictions with three dimensions that correspond to the pore sizes Lᵢ (1≦i≦N−1), the experimental wavenumbers qᵢ (1≦i≦m) and the experimental MR angle φᵢ (1≦i≦k).

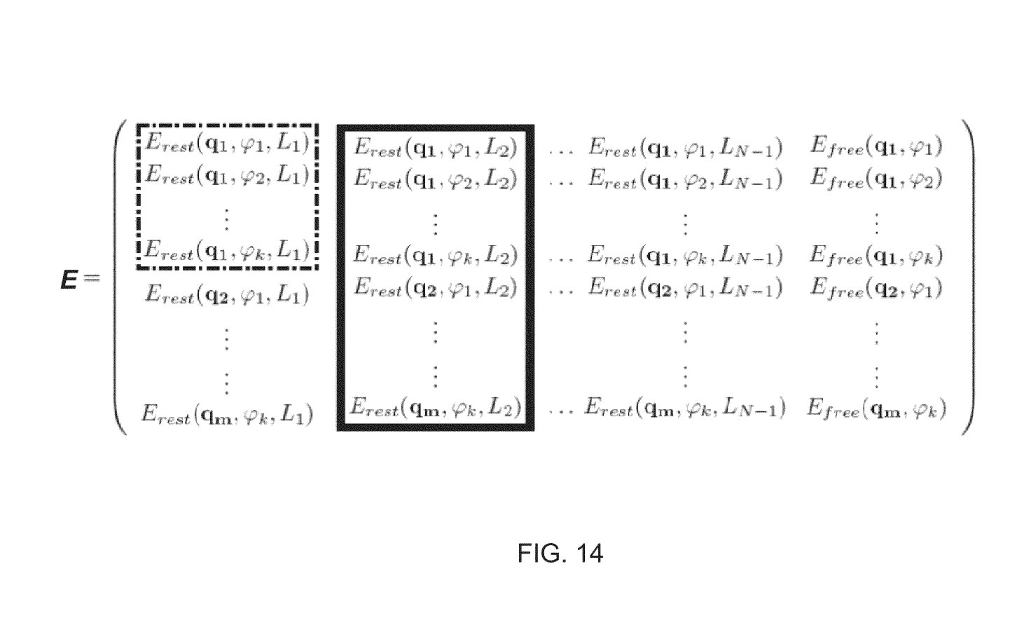

FIG. 14 shows an example of a three-dimensional set of equations which is formulated to a matrix. L is constant in every column (with the exception of the Nth column, which is free water), represented by the solid line block. q is constant and φ varies in every block represented by the dot-dash line.

This matrix implies that the continuous pores' sizes distribution is approximated by a discrete set of pores' sizes, preferably, but not necessarily, evenly spaced. The matrix E was created by selecting N−1 different pore radii, and then calculating the signal curve from them under all the experimental parameters of the Angular d-PFG q-space sequence. To account for practical experimental conditions, the Nth column is the calculated signal of non restricted water molecules E_{free} (qᵢ, φᵢ). This is because typical examples contain free water. The inverse problem of reconstruction of pores' sizes distribution became linear,

E_{data}=E·f,

where E_{data} is a vector representing the experimental data (the superposed NMR signal curves, in the present example), and f is the vector of coefficients which is to be calculated. The calculation was implemented using Matlab® (R2009a, The MathWorks®, Natick, Mass.) in house algorithms.

### REFERENCES

[1] Timothy E J Johansen-Berg, Heidi and Behrens. Diffusion MRI: from quantitative measurement to in-vivo neuroanatomy. Academic Press, 2009.
[2] Per Malmberg and Ha kan Nygren. A method for evaluating the influence of porosity on the early reactions of blood with materials. Biomaterials, 23(1):247-253, January 2002.
[3] N. J Dunne, J. F Orr, M. T Mushipe, and R. J. Eveleigh. The relationship between porosity and fatigue characteristics of bone cements. Biomaterials, 24(2):239-245, January 2003.
[4] Jonathan J Elsner and Meital Zilberman. Antibiotic-eluting bioresorbable composite fibers for wound healing applications: microstructure, drug delivery and mechanical properties. Acta biomaterialia, 5(8):2872-83, October 2009.
[5] Vassilis Karageorgiou and David Kaplan. Porosity of 3D biomaterial scaffolds and osteogenesis. Biomaterials, 26(27):5474-91, September 2005.
[6] Jonathan J Elsner and Meital Zilberman. Antibiotic-eluting bioresorbable composite fibers for wound healing applications: microstructure, drug delivery and mechanical properties. Acta biomaterialia, 5(8):2872-83, October 2009.
[7] Orly Grinberg, Itzhak Binderman, Hila Bahar, and Meital Zilberman. Highly porous bioresorbable scaffolds with controlled release of bioactive agents for tissue-regeneration applications. Acta biomaterialia, 6(4):1278-87, April 2010.
[8] P. T. Callaghan, A. Coy, D. MacGowan, K. J. Packer, and F. O. Zelaya. Diffraction-like effects in NMR diffusion studies of fluids in porous solids. Nature, 351:467-469, 1991.
[9] P. T. Callaghan. NMR Imaging, NMR Diffraction and Applications of Pulsed Gradient Spin Echoes In Porous Media. Science, 14:701-709, 1996.
[10] P J Basser, J Mattiello, and D LeBihan. MR diffusion tensor spectroscopy and imaging. Biophysical journal, 66(1):259-67, January 1994.
[11] M E Komlosh, F Horkay, R Z Freidlin, U Nevo, Y Assaf, and P J. Basser. Detection of microscopic anisotropy in gray matter and in a novel tissue phantom using double Pulsed Gradient Spin Echo MR. Journal of magnetic resonance (San Diego, Calif.: 1997), 189(1):38-45, November 2007.
[12] Noam Shemesh, Evren Ozarslan, Tal Adiri, Peter J Basser, and Yoram Cohen. Noninvasive bipolar double-pulsed-field-gradient NMR reveals signatures for pore size and shape in polydisperse, randomly oriented, inhomogeneous porous media. The Journal of chemical physics, 133(4):044705, July 2010.
[13] Noam Shemesh, Evren Ozarslan, Michal E Komlosh, Peter J Basser, and Yoram Cohen. From single-pulsed field gradient to double-pulsed field gradient MR: gleaning new microstructural information and developing new forms of contrast in MRI. NMR in biomedicine, (November 2009):757-780, August 2010.
[14] Denis S Grebenkov. Laplacian Eigenfunctions in NMR. I. A Numerical Tool. Concepts In Magnetic Resonance, (1):277-301, 2008.
[15 R. F. Karlicek and I. J. Lowe. A modified pulsed gradient technique for measuring diffusion in the presence of large background gradients. Journal of Magnetic Resonance (1969), 37(1):75-91, January 1980.
[16] Evren Ozarslan, Noam Shemesh, and Peter J. Basser. A general framework to quantify the effect of restricted diffusion on the NMR signal with applications to double pulsed field gradient NMR experiments. The Journal of chemical physics, 130(10):104702, March 2009.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A method of magnetic resonance analysis of a porous structure, comprising:
obtaining a recorded magnetic resonance signal as a function of both a magnetic resonance wavevector q and a magnetic resonance angle φ, in response to a series of magnetic resonance experiments, each featuring a plurality of pairs of bipolar gradient pulse subsequences being characterized by a respective magnetic resonance wavevector q and a respective magnetic resonance angle φ, said φ being an angle between gradient directions of said bipolar gradient pulse subsequences;
using a processing system for performing an at least three-dimensional analysis of said magnetic resonance signal, so as to extract a pore size distribution from the structure.

2. The method according to claim 1, wherein said three-dimensional analysis comprises solving a linearized three-dimensional set of equations.

3. The method of claim 2, wherein said linearized three-dimensional set of equations is formula table into a matrix whose columns represent pore sizes wherein the entries in each column vary as a function of said magnetic resonance wavevector q and said magnetic resonance angle φ.

4. The method of claim 3, further comprising selecting a plurality of predetermined and different pore sizes, and calculating an expected signal for each value of said magnetic resonance wavevector q and said magnetic resonance angle φ.

5. The method according to claim 3, wherein said analysis comprises calculating a vector of coefficient for said matrix.

6. The method according to claim 1, further comprising, for each experiment, generating a respective plurality of pairs of bipolar gradient pulse subsequences and acquiring a respective magnetic resonance signal generated in response to said pairs of bipolar gradient pulse subsequences.

7. The method according to claim 1, wherein the structure comprises at least one object selected from the group consisting of a sediment, a rock, a heterogeneous catalyst, a porous polymer, an emulsion product, a biological cell, a tissue, a central-nervous-system tissue, quartz sand and a yeast cell.

8. The method according to claim 1, wherein the structure comprises at least one structure selected from the group consisting of soil and rock and the method further comprising using said pore size distribution for assessing hydrocarbon content or production potential of the structure.

9. The method according to claim 1, wherein the structure is wet.

10. The method according to claim 1, wherein the structure is immersed in a liquid.

11. A computer software product, comprising a computer-readable medium in which program instructions are stored, which instructions, when read by a computer, cause the computer to receive a recorded magnetic resonance signal, to analyze said signal according to the method of claims 1.

12. A system for magnetic resonance analysis, comprising;
a radiofrequency system configured for generating a plurality of pairs of bipolar gradient pulse subsequences, and acquiring a magnetic resonance signal as a function of both a magnetic resonance wavevector q and a magnetic resonance angle φ, in response to a series of magnetic resonance experiments, each featuring a plurality of pairs of bipolar gradient pulse subsequences being characterized by a respective magnetic resonance wavevector q and a respective magnetic resonance angle φ, said φ being an angle between gradient directions of said bipolar gradient pulse subsequences; and
a processing system configured for performing an at least three-dimensional analysis of said magnetic resonance signal, so as to extract a pore size distribution from the structure.

13. The system according to claim 12, wherein said processing system is configured for solving a linearized three-dimensional set of equations.

14. The system of claim 13, wherein said linearized three-dimensional set of equations is formula table into a matrix whose columns represent pore sizes wherein the entries in each column vary as a function of said magnetic resonance wavevector q and said magnetic resonance angle φ.

15. The system of claim 14, wherein said processing system is configured for calculating, for each of a plurality of predetermined and different pore sizes, an expected signal for each value of said magnetic resonance wavevector q and said magnetic resonance angle φ.

16. The system according to claim 14, wherein said processing system is configured for calculating a vector of coefficient for said matrix.

17. The system according to claim 12, wherein the structure comprises at least one structure selected from the group consisting of soil and rock and the processing system is configured for assessing hydrocarbon content or production potential of the structure based on said pore size distribution.
